(19) United States
(12) Patent Application Publication
(10) Pub. No.: US 2011/0001536 A1
(43) Pub. Date: Jan. 6, 2011

(54) STATIC LATCH

(75) Inventor: Yung-Feng Lin, Taoyuan County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MACRONIX INTERNATIONAL CO., LTD., Hsinchu (TW)

(21) Appl. No.: 12/496,712

(22) Filed: Jul. 2, 2009

(51) Int. Cl. H03K 3/356

(52) U.S. Cl. 327/211

(57) ABSTRACT

A static latch includes a clock-based driver, an actuation circuit, and a weak latched unit. The clock-based driver includes first node, second node, a driving unit, first pass switch, and second pass switch. The driving unit drives the first node corresponding to first voltage in response to first level of an input signal and drives the second node having second voltage in response to second level of the input signal. The first pass switch drives an output node having a latched signal corresponding to the first voltage in response to the clock signal. The second pass switch drives the output node corresponding to the second voltage in response to the inverted clock signal. The actuation circuit drives the output node corresponding to the second voltage in response to the clock signal. The weak latch unit keeps the level of the latched signal when the static latch is disabled.

### BACKGROUND OF THE INVENTION

1. Field of the Invention

The invention relates in general to a latch, and more particularly to a static latch applied in a memory.

2. Description of the Related Art

Referring to FIG. 1, a circuit diagram of a conventional latch is shown. Conventionally, a latch 1 includes a node N, an inverter IV, a pass switch PG, and a latch unit LL. The inverter IV generates an inverted clock signal CKB in response to a clock signal CK. The pass switch receives an input signal SIN and provides the input signal SIN to the node N to establish a voltage signal SV in response to a high signal level of the clock signal CK and a low signal level of the inverted clock signal CKB. The latch unit LL includes a driving inverter DI for providing a latched signal QB in response to the voltage signal SV. The latch unit LL further includes a feedback inverter FBI for negatively feed the latched signal QB back to the node N so as to keep the voltage level of the voltage signal SV and the latched signal QB.

Each of the pass switch PG and the driving inverter DI needs a period of delay time for providing stable output signal. In other words, two gate delay time are needed for the latch 1 to establish its output signal (that is the latched signal QB) after the clock signal CK reaches its high level. In the present situation, there is a greater demand for high speed clock-based operation. In this regards, the delay time would lead to serious problems of circuitry malfunction in case that the clock rate gets higher so that a clock cycle is barely sufficient for the latch 1 to obtain the latched signal QB.

### SUMMARY OF THE INVENTION

The invention is directed to a static latch for latching a signal. The static latch according to the invention employs a clock-based driver, which is controlled by a clock signal and an inverted clock signal, to provide the latched signal in response to an input signal. The static latch according to the invention further employs an actuation circuit for driving the latched signal with the clock-based driver. In comparison to the conventional latch, the static latch according to the invention can result in a reduced delay time for the latched signal to be driven from a clock rising to data validation effectively.

According to the present invention, a static latch is provided. The static latch includes a clock-based driver, a first actuation circuit, and a latched unit. The clock-based driver includes first node, second node, a driving unit, a first pass switch, and a second pass switch. The driving unit provides a first voltage to the first node in response to a first level of an input signal and provides a second voltage to the second node in response to a second level of the input signal. The first pass switch provides the first voltage on the first node to an output node in response to a clock signal and makes the latched signal corresponding to a level of the first voltage. The second pass switch provides the second voltage on the second node to the output node in response to an inverted clock signal and makes the latched signal corresponding to a level of the second voltage. The first actuation circuit provides the second voltage on the second node to the output node in response to the clock signal. The latch unit keeps the level of the latched signal.

According to the present invention, a static latch is provided. The static latch includes a driver, an actuator, and a latch unit. The driver provides a first voltage to a first node in response to an input signal and provides the first voltage on the first node to an output node of the static latch in response to a clock signal. The driver provides a second voltage to a second node in response to the input signal and provides the second voltage on the second node to the output node in response to the clock signal. The actuator provides the second voltage on the second node to the output node in response to the clock signal. The latch unit keeps the voltage on the output node when the clock signal is disabled.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a circuit diagram of a conventional latch.

FIG. 2 is a circuit diagram of the static latch of a first embodiment of the invention.

FIG. 3A is a simulated result of the related signals related to the conventional latch 1.

FIG. 3B is a simulated result of the related signals related to the static latch 2 of the embodiment of the invention.

FIG. 4 is a circuit diagram of the static latch of a second embodiment of the invention.

FIG. 5 is a circuit diagram of the static latch of a third embodiment of the invention.

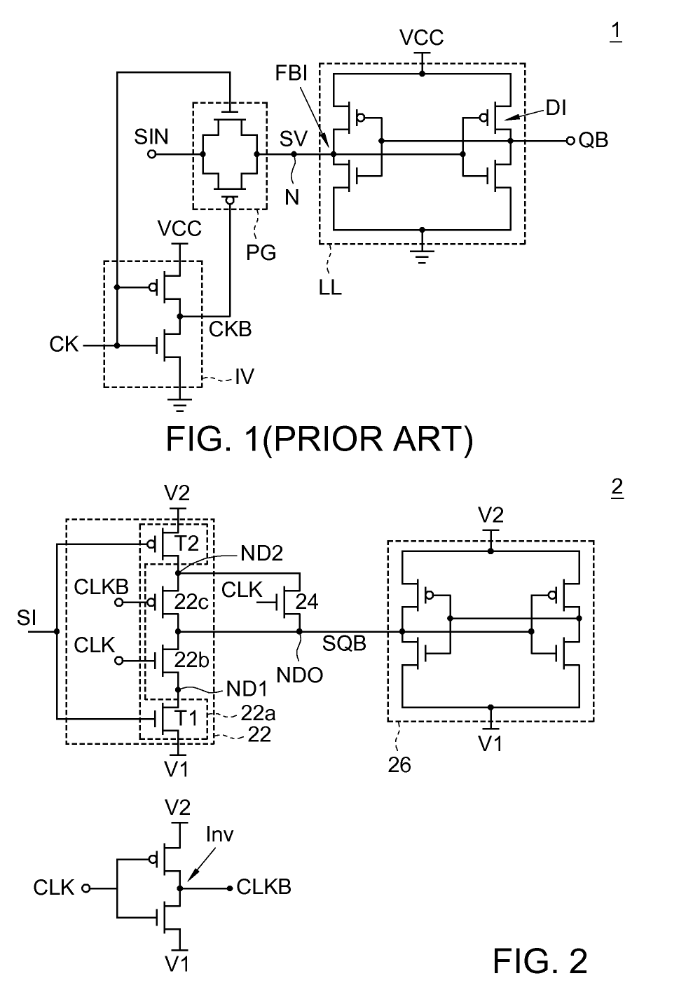

### DETAILED DESCRIPTION OF THE INVENTION

The static latch of the present embodiment of the invention employs a clock-based driver, which is controlled by a clock signal and an inverted clock signal, to drive a latched signal based on an input signal. The static latch further employs an actuation circuit for driving the latched signal together with the clock-based driver.

### First Embodiment

Referring to FIG. 2, a circuit diagram of the static latch of a first embodiment of the invention is shown. The static latch 2 is controlled by a clock signal CLK and an inverted clock signal CLKB and stores a latched signal SQB on an output node NDO in response to an input signal SI. For example, the static latch 2 includes an inverter Inv for generating the inverse clock signal CLKB based on the clock signal CLK. The static latch 2 includes a clock-based driver 22, an actuation circuit or an actuator 24, and a weak latch unit 26. The clock-based driver 22, the actuation circuit 24, and the weak latch unit 26 are all coupled to the output node NDO.

The clock-based driver 22 includes nodes ND1, ND2, a driving unit 22a, and pass switches 22b and 22c. The driving unit 22a and the pass switch 22b are coupled to the node ND1. The driving unit 22a and the pass switch 22c are coupled to the node ND2.

The driving unit 22a provides a voltage V1 to the node ND1 in response to a first level (a high signal level, for example) of the input signal S1. For example, the voltage V1 is the ground voltage. The driving unit 22a provides a voltage V2 to the second node ND2 in response to a second level (a low signal level, for example) of the input signal SI. For example, the voltage V2 is the power supply voltage, a high voltage for example, of the static latch 2.

For example, the driving unit 22a includes an N-type metal oxide semiconductor (NMOS) transistor T1 and a P-type metal oxide semiconductor (PMOS) transistor T2. The NMOS transistor T1 has a gate receiving the input signal SI, a source receiving the voltage V1, and a drain coupled to the node ND1. The NMOS transistor T1 is turned on based on the first level (e.g. the high signal level) of the input signal SI to provide the voltage V1 (e.g. the ground voltage) to the node ND1. The PMOS transistor has a gate receiving the input signal SI, a source receiving the voltage V2, and a drain coupled to the node ND2. The PMOS transistor T2 is turned on based on the second level (e.g. the low signal level) of the input signal SI to provide the voltage V2 (e.g. the power supply voltage) to the node ND2. Since the input signal SI is at either the high level or low level during the operation of the static latch 2, only one of the transistors T1 and T2 is turned on and the other is turned off and keeps the corresponding node (i.e. ND1 or ND2) floating.

The pass switch 22b provides the voltage, which is substantially equal to the voltage V1, on the node ND1 to drive the output node NDO in response to the clock signal CLK and makes the latched signal SQB corresponding to a level of the voltage V1. For example, the pass switch 22b includes an NMOS having a gate receiving the clock signal CLK, a source coupled to the node ND1, and a drain coupled to the output node NDO. The pass switch 22b is turned on in response to a high level of the clock signal CLK to provide the voltage on the node ND1 to the output node NDO. If the input signal SI is at the high level, the voltage on the node ND1 (e.g. the (e.g. the ground voltage) is provided to the output node NDO, such that the latched signal SQB is driven to the ground voltage.

The pass switch 22c provides the voltage, which is substantially equal to the voltage V2, on the node ND2 to drive the output node NDO in response to the inverted clock signal CLKB and makes the latched signal SQB corresponding to a level of the voltage V2. For example, the pass switch 22c includes a PMOS having a gate receiving the inverted clock signal CLKB, a source coupled to the node ND2, and a drain coupled to the output node NDO. The pass switch 22c is turned on in response to a low level of the inverted clock signal CLKB to provide the voltage on the node ND2 to the output node NDO. If the input signal SI is at the low level, the voltage on the node ND2 (i.e. the power supply voltage) is provided to the output node NDO, such that the latched signal SQB is driven to the power supply voltage.

Compared with an ideal inversed clock signal of the clock signal CLK, the inverted clock signal CLKB is delayed by a gate delay of the inverter Inv since the inverted clock signal CKLB is generated by the inverter Inv in response to the clock signal CLK. Thus, in comparison with the operation of the pass switch 22b to turn on and to provide the voltage on the node ND1 to the output node, the operation of the pass switch 22c is delayed by the gate delay. Consequently, the time needed for the latched signal SQB to be charged to the voltage V2 is longer than that needed for the latched signal SQB to be discharged to the voltage V1. What is even worse is that the pass switch 22c employs the PMOS, which normally has a weaker driving ability than that of the NMOS. As a result, the time needed for the latched signal SQB to be charged to the voltage V2 will be more severely delayed due to the lack of the driving ability of the PMOS in the pass switch 22c.

In an example, the actuation circuit 24 is incorporated in the static latch 2 for providing the voltage on the node ND2 to the output node NDO together with the pass switch 22c in response to the clock signal CLK, so as to shorten the time needed for the latched signal SQB to be charged to the voltage V2. For example, the actuation circuit 24 includes an NMOS transistor having a gate receiving the clock signal CLK, a drain coupled to the node ND2, and a source coupled to the output node NDO. The NMOS in the actuation circuit 24 is turned on in response to the high level of the clock signal CLK to provide the voltage on the node ND2 to the output node NDO. Thus, the operation of driving the latched signal SQB to the voltage V2 will not be delayed by the gate delay of the inverter Inv and the driving ability driving the latched signal SQB to the voltage V2 can be effectively enhanced by the NMOS in the actuation circuit 24. Consequently, the time needed for the latched signal SQB to be charged to the voltage V2 can be effectively shortened.

The weak latch unit 26 keeps the level of the latched signal SQB when the clock signal CLK is disabled. For example, the weak latch unit 26 includes a feedback inverter loop for keeping the level of the latched signal. In an example, two inverters are included in the feedback inverter loop and the two inverters are both realized with small element size and provide little driving ability for the latched signal SQB.

In an example, the input signal SI has the stable high level or the stable low level before the rising edge of the clock signal CLK and the falling edge of the inverted clock signal CLKB. Thus, the voltages on the nodes ND1 and ND2 can be effectively driven to the voltages V1 and V2 respectively before the clock signal CLK goes to the high level. Consequently, the voltages on the nodes ND1 and ND2 can be readily set to drive the output node NDO when the clock signal CLK goes high.

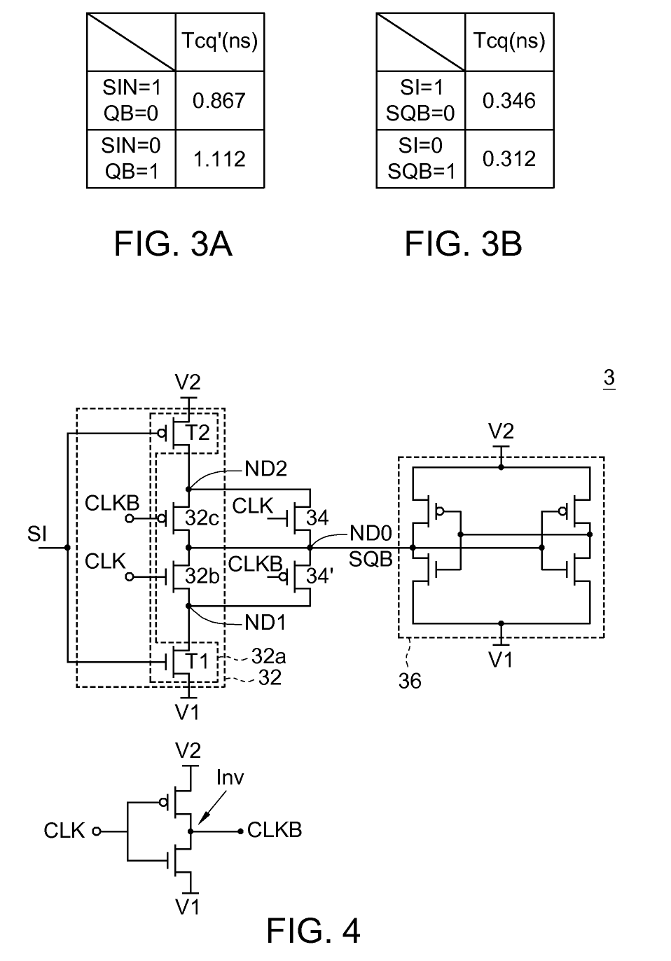

Referring to FIG. 3A, a simulated result of the delay time related to the conventional latch 1 is shown. A same simulation condition, a worst case circuit condition for example, is applied on the conventional latch 1 and the static latch 2 to obtain the simulation results shown in FIG. 3A. For example, the input signal SIN reaches a stable signal level before the transition of the clock signal CK. A time interval Tcq′ is defined as the delay from the transition of the clock signal CK to the transition of the latched signal QB. In other words, the time interval Tcq′ indicates the total delay time for the transition of the latched signal QB. When the input signal SIN corresponds to a high signal level (indicating the logic value 1), the time interval Tcq′ (i.e. the time delay for the latched signal QB to go from a high signal level to a low signal level) is equal to 0.867 nanosecond (ns). When the input signal SIN the input signal SIN corresponds to a low signal level (indicating the logic value 0), the time interval Tcq′ (i.e. the time delay for the latched signal QB to go from the low signal level to the high signal level) is equal to 1.112 ns.

Referring to FIG. 3B, a simulated result of the delay time related to the static latch 2 of the embodiment of the invention is shown. Under substantially the same circuit simulation condition, a time interval Tcq is defined as the delay from the transition of the clock signal CLK to the transition of the latched signal SQB. When the input signal SI corresponds to a high signal level and the latched signal SQB corresponds to a low signal level, the time interval Tcq is equal to 0.346 ns. When the input signal SI corresponds to a low signal level and the latched signal SQB corresponds to a high signal level, the time interval Tcq is equal to 0.312 ns.

Thus, in comparison with the conventional latch 1, it can be obtained that the static latch 2 of the present embodiment of the invention can effectively reduce the time delay for the transitions of the latched signal from FIG. 3A and 3B, Besides, It can also be obtained that the actuation circuit 24 can effectively reduce the delay time needed for the latched signal to go from the low signal level to the high signal level by comparing the time interval Tcq′ equal to 1.112 ns and the time interval Tcq equal to 0.312 ns due to the employment of the actuation circuit 24.

### Second Embodiment

Referring to FIG. 4, a static latch according to a second embodiment of the invention is shown. The static latch 3 shown in FIG. 4 is different from the static latch 2 shown in FIG. 2 in that it further includes actuation circuit 34′, which includes a PMOS, for providing the voltage on the node ND1 to the output node NDO together with the pass switch 32b, in response to the inverted clock signal CLKB. It can be obtained that the equivalent resistance between the node ND1 and the output node NDO can be reduced due to the actuation circuit 34′ connected with the pass switch 32b in parallel. Thus, the time needed for the latched signal SQB to be discharged to the voltage V1 can also be shortened.

### Third Embodiment

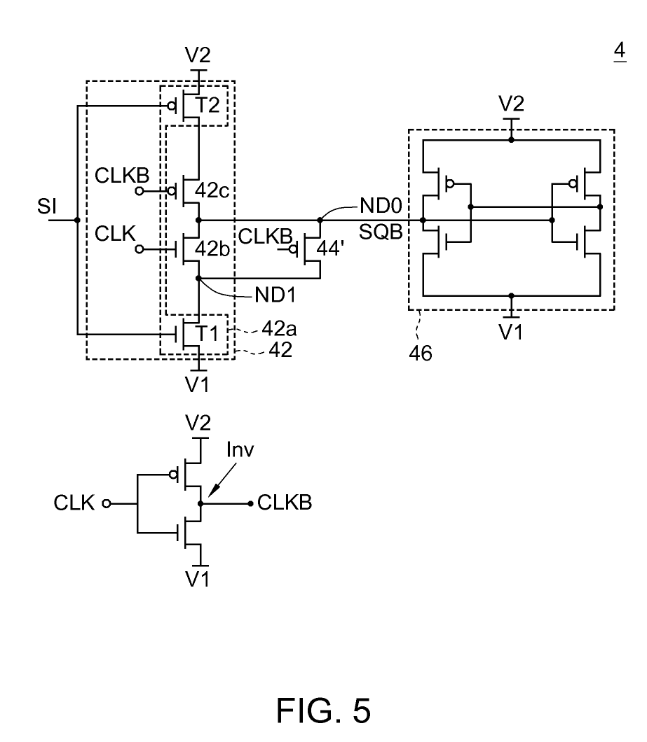

Referring to FIG. 5, shows a static latch according to a third embodiment of the invention is shown. The static latch 4 shown in FIG. 5 is different from the static latch 3 shown in FIG. 4 in that it only includes only one actuation circuit 44′, which has substantially the same circuit structure and function as the actuation circuit 34′ for providing the voltage on the node ND1 to the output node NDO together with the pass switch 42b, in response to the inverted clock signal CLKB. In the static latch 4, the actuation circuit corresponding to the actuation circuits 24 and 34 is omitted. It can be obtained that the equivalent resistance between the node ND1 and the output node NDO can be reduced due to the actuation circuit 44′ connected with the pass switch 42b in parallel. Thus, the time needed for the latched signal SQB to be discharged to the voltage V1 can also be shortened.

As shown above, the static latch according to the above mentioned embodiments of the invention includes a clock-based driver, which is controlled by a clock signal and an inverted clock signal, to drive a latched signal based on an input signal. An actuation circuit is further employed for driving the latched signal with the clock-based driver. Thus, in comparison to the conventional latch, the static latch according to the above mentioned embodiments of the invention can result in a reduced delay time for the latched signal to be driven from an initial voltage to an end voltage effectively.

While the invention has been described by way of examples and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A static latch comprising:
a clock-based driver comprising:
a first node and a second node;
a driving unit, providing a first voltage to the first node in response to a first level of an input signal and providing a second voltage to the second node in response to a second level of the input signal;
a first pass switch, for providing the first voltage on the first node to an output node in response to a clock signal and making a latched signal on the output node corresponding to a level of the first voltage; and
a second pass switch, for providing the second voltage on the second node to the output node in response to an inverted clock signal and making the latched signal corresponding to a level of the second voltage;
a first actuation circuit, for providing the second voltage on the second node to the output node in response to the clock signal; and
a latch unit, for keeping the level of the latched signal when the clock signal is disabled.

2. The static latch according to claim 1, further comprising:
a second actuation circuit, for providing the first voltage on the first node to the output node in response to the inverted clock signal.

3. The static latch according to claim 2, wherein the second actuation circuit comprises:
a transistor, having a gate receiving the inverted clock signal, a first end receiving the first voltage, and a second end coupled to the output node.

4. The static latch according to claim 1, wherein the first actuation circuit comprises:
a transistor, having a gate receiving the clock signal, a first end receiving the second voltage, and a second end coupled to the output node.

5. The static latch according to claim 1, wherein the driving unit comprises:
a first transistor, having a gate receiving the input signal, a first end receiving the first voltage, and a second end coupled to the first node; and
a second transistor, having a gate receiving the input signal, a first end receiving the second voltage, and a second end coupled to the second node.

6. The static latch according to claim 1, wherein the first pass switch comprises:
a transistor, having a gate receiving the clock signal, a first end coupled to the first node, and a second end coupled to the output node.

7. The static latch according to claim 1, wherein the second pass switch comprises:
a transistor, having a gate receiving the inverted clock signal, a first end coupled to the second node, and a second end coupled to the output node.

8. The static latch according to claim 1, wherein the latch unit comprises:
a feedback inverter loop, for keeping the level of the latched signal.

9. The static latch according to claim 1, further comprising:
an inverter, for generating the inverted clock signal in response to the clock signal.

10. A static latch, comprising:
a driver for providing a first voltage to a first node in response to an input signal and for providing the first voltage on the first node to an output node of the static latch in response to a clock signal, and for providing a second voltage to a second node in response to the input signal and for providing the second voltage on the second node to the output node in response to the clock signal;
an actuator for providing the second voltage on the second node to the output node in response to the clock signal; and
a latch unit for keeping the voltage on the output node when the clock signal is disabled.

11. The static latch according to claim 10, wherein the driver comprise:
a first node and a second node;
a driving unit, providing the first voltage to the first node in response to a first level of the input signal and providing the second voltage to the second node in response to a second level of the input signal;
a first pass switch, for providing the first voltage on the first node to the output node in response to the clock signal and making a latched signal on the output node corresponding to a level of the first voltage; and
a second pass switch, for providing the second voltage on the second node to the output node in response to an inverted clock signal and making the latched signal corresponding to a level of the second voltage.

12. The static latch according to claim 11, further comprising:
a second actuation circuit, for providing the first voltage on the first node to the output node in response to the inverted clock signal.

13. The static latch according to claim 12, wherein the second actuation circuit comprises:
a transistor, having a gate receiving the inverted clock signal, a first end receiving the first voltage, and a second end coupled to the output node.

14. The static latch according to claim 11, wherein the driving unit comprises:
a first transistor, having a gate receiving the input signal, a first end receiving the first voltage, and a second end coupled to the first node; and
a second transistor, having a gate receiving the input signal, a first end receiving the second voltage, and a second end coupled to the second node.

15. The static latch according to claim 11, wherein the first pass switch comprises:
a transistor, having a gate receiving the clock signal, a first end coupled to the first node, and a second end coupled to the output node.

16. The static latch according to claim 11, wherein the second pass switch comprises:
a transistor, having a gate receiving the inverted clock signal, a first end coupled to the second node, and a second end coupled to the output node.

17. The static latch according to claim 11, further comprising:
an inverter, for generating the inverted clock signal in response to the clock signal.

18. The static latch according to claim 10, wherein the first actuation circuit comprises:
a transistor, having a gate receiving the clock signal, a first end receiving the second voltage, and a second end coupled to the output node.

19. The static latch according to claim 10, wherein the latch unit comprises:
a feedback inverter loop, for keeping the level of the latched signal.
